(19) United States
(12) Patent Application Publication
(10) Pub. No.: US 2016/0211346 A1
(43) Pub. Date: Jul. 21, 2016

(54) Epitaxial Channel Transistors and Die With Diffusion Doped Channels

(71) Applicant: Mie Fujitsu Semiconductor Limited, Kuwana (JP)

(72) Inventors: Lucian Shifren, San Jose, CA (US); Pushkar Ranade, Los Gatos, CA (US); Scott E. Thompson, Gainesville, FL (US)

(21) Appl. No.: 15/082,926

(22) Filed: Mar. 28, 2016

Related U.S. Application Data
(62) Division of application No. 13/469,201, filed on May 11, 2012.
(60) Provisional application No. 61/484,963, filed on May 11, 2011.

(51) Int. Cl. H01L 29/66; H01L 29/78; H01L 29/06

(52) U.S. Cl. CPC H01L 29/66537; H01L 29/0638; H01L 29/0653; H01L 29/7838

(57) ABSTRACT

Semiconductor structures can be fabricated by implanting a screen layer into a substrate, with the screen layer formed at least in part from a low diffusion dopant species. An epitaxial channel of silicon or silicon germanium is formed above the screen layer, and the same or different dopant species is diffused from the screen layer into the epitaxial channel layer to form a slightly depleted channel (SDC) transistor. Such transistors have inferior threshold voltage matching characteristics compared to deeply depleted channel (DDC) transistors, but can be more easily matched to legacy doped channel transistors in system on a chip (SoC) or multiple transistor semiconductor die.

### CROSS-REFERENCE TO RELATED APPLICATIONS

This non-provisional application claims the benefit of U.S. Provisional Application No. 61/484,963 entitled “Improved Epitaxial Channel Transistor” filed May 11, 2011, the entirety of which is hereby incorporated herein by reference.

### FIELD OF THE INVENTION

Improved epitaxial channel transistors and manufacturing processes for nanometer scale transistors for mixed signal, system on a chip, or other electronic die are described.

### BACKGROUND

Modern integrated circuit die typically include millions of field effect transistors (FETs). These transistors are typically not identical throughout an integrated circuit, but rather are divided into categories that are based on size and various physical, material, or electrical properties. The aforementioned categories are referred to herein as transistor device types. Illustrative transistor device types that are commonly found in integrated circuits include but are not necessarily limited to: p-channel FETs, n-channel FETs, FETs tailored for digital or analog circuit applications, high-voltage FETs, high/normal/low frequency FETs, FETs optimized to work at distinct voltages or voltage ranges, and low/high power FETs.

There is a continuing commercial pressure to reduce transistor size and power requirements for all transistor device types. While smaller and more power efficient transistor device types can be substituted for older transistor device types, this can require a substantial amount of circuit redesign to accommodate the changes in electrical properties. For many applications, designers would like to minimize such required circuit design. One approach is to adapt new transistor manufacturing processes and structures to support features that mimic or emulate older transistor designs (i.e., legacy transistors). However, if the new processes for forming transistors are sufficiently distinct, formation of legacy transistors can be difficult or impossible.

### BRIEF DESCRIPTION OF THE FIGURES

For a more complete understanding of the present disclosure, reference is made to the following description taken in conjunction with the accompanying drawings, wherein like reference numerals represent like parts, in which:

FIG. 1 illustrates a wafer having an implanted screen layer and a blanket deposited epitaxial layer;

FIG. 2 illustrates four representative and distinct transistor device types that can be supported on the wafer and die of FIG. 1;

FIG. 3 schematically illustrates four channel dopant profiles of the transistor device types illustrated in FIG. 2;

FIG. 4 is a representative dopant profile for a slightly depleted channel (SDC) pFET transistor;

FIG. 5 is a representative dopant profile for a variant SDC transistor;

FIG. 6 is an illustration of selected process steps in formation of a blanket epitaxial channel transistor; and

FIGS. 7-10 illustrate intermediate structures formed during the process of FIG. 6.

### DETAILED DESCRIPTION

The following Detailed Description refers to accompanying drawings to illustrate exemplary embodiments consistent with the invention. References in the Detailed Description to “one exemplary embodiment,” “an illustrative embodiment,” “an exemplary embodiment,” and so on, indicate that the exemplary embodiment described may include a particular feature, structure, or characteristic, but every exemplary or illustrative embodiment may not necessarily include that particular feature, structure, or characteristic. Moreover, such phrases are not necessarily referring to the same exemplary embodiment. Further, when a particular feature, structure, or characteristic is described in connection with an embodiment, it is within the knowledge of those skilled in the relevant art(s) to affect such feature, structure, or characteristic in connection with other embodiments whether or not explicitly described.

The exemplary embodiments described herein are provided for illustrative purposes, and are not limiting. Other embodiments are possible, and modifications may be made to the exemplary embodiments within the spirit and scope of the invention. Therefore, the Detailed Description is not meant to limit the invention. Rather, the scope of the invention is defined only in accordance with the subjoined claims and their equivalents.

The following Detailed Description of the exemplary embodiments will so fully reveal the general nature of the embodiments that others can, by applying knowledge of those skilled in relevant art(s), readily modify and/or adapt for various applications such exemplary embodiments without undue experimentation. Therefore, such adaptations and modifications are intended to be within the meaning and plurality of equivalents of the exemplary embodiments. It is to be understood that the phraseology or terminology herein is for the purpose of description and not of limitation, such that the terminology or phraseology of the present specification is to be interpreted by those skilled in relevant art(s) in light of the teachings herein.

In this disclosure, FET refers to field effect transistor. An n-channel FET can be referred to herein as an n-FET. A p-channel FET is referred to herein as a p-FET. As used herein, “gate” refers to the gate terminal of a FET. The gate terminal of a FET is also referred to in this field as a “gate electrode.” Gates are formable from highly doped silicon, metals, and/or metal alloys. Source/drain (S/D) terminals refer to the terminals of a FET, between which conduction occurs under the influence of an electric field subsequent to formation of a charge inversion layer of the semiconductor surface under the influence of an electric field resulting from a voltage applied to the gate terminal of the FET. A threshold voltage (Vt) is the minimum gate voltage where formation of the inversion layer allows the flow of electrons between the source/drain terminals.

Generally, the source and drain terminals of a FET are fabricated such that they are geometrically symmetrical. With geometrically symmetrical source and drain terminals, it is common to simply refer to these terminals as source/drain terminals and this nomenclature is used herein. Designers often designate a particular source/drain terminal to be a “source” or a “drain” on the basis of the voltage to be applied to that terminal when the FET is operated in a circuit. Substrate, as used herein, refers to the physical object that is transformed by various process operations into the desired microelectronic configuration. Silicon wafers are a commonly used substrate in the manufacture of integrated circuits. The term vertical, as used herein, means substantially perpendicular to the surface of a substrate.

Epitaxial layer refers to a layer of single crystal semiconductor material such as silicon or silicon germanium that are grown or deposited on a substrate and have a crystalline structure that matches or is similar to the substrate crystal structure. An epitaxial layer is commonly referred to as an “epi” layer. The epitaxial layer can be grown without dopants. Commonly, epitaxial layers are selectively implanted with dopants to adjust the threshold voltage, with different levels of dopants changing the threshold voltage and other device characteristics of a transistor.

In this disclosure, multiple transistor types can be formed in a substantially undoped epitaxial layer by differential out-diffusion from a doped underlayer rather than through post-growth doped implant. The substantially undoped layer can be a common blanket epitaxial layer that extends across the different devices, or may be a selectively grown epitaxial layer associated with a single transistor. Differential out-diffusion from transistor to transistor affects the thickness of the substantially undoped layer and therefore changes a resulting threshold voltage for the transistor.

Many integrated circuit designs benefit from the availability of a variety of transistor device types that can be included in those integrated circuits. Device types can differ by operating voltage (Vdd), threshold voltage (Vt), or electrical response characteristics including switching speed and power leakage. The availability of multiple transistor device types provides engineers with the resources to produce optimized circuit designs as well as to produce circuit designs that might otherwise be unachievable if limited to a small number of transistor device types. As a practical matter, it is desirable that each integrated circuit on a wafer be able to incorporate all, or any subset of, the range of transistor device types available in an integrated circuit manufacturing process while achieving a limited variation in threshold voltage both locally and globally.

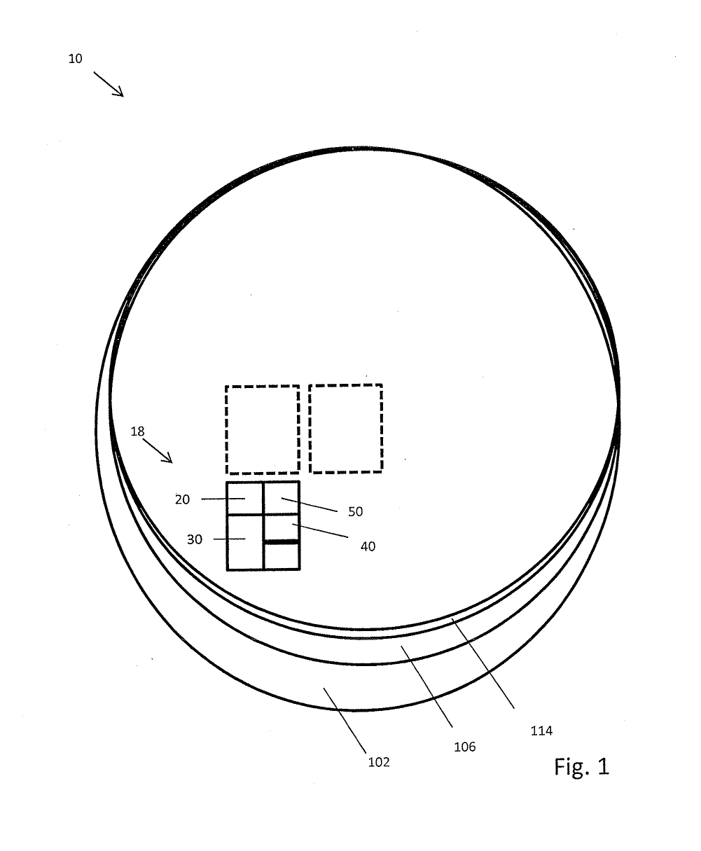

Disclosed herein are exemplary semiconductor structures, along with methods for making such structures, wherein a plurality of transistor device types are provided within an integrated circuit and/or within a wafer containing a plurality of integrated circuits. A semiconductor wafer 10 supporting multiple die 18 is illustrated (not to scale) in FIG. 1. Each die 18 can support multiple transistor device types, including high and low power digital transistors, analog transistors, transistors optimized for power, sensing, matching, or any other desired transistor functionality. As will be appreciated, the device types can be manufactured alone or in combination with each other, permitting creation of complex system on a chip (SoC) or similar die that optionally include analog, digital, legacy, or improved transistors such as described in this disclosure. For example, four useful device blocks in a single die are illustrated as follows: block 20 outlines a collection of deeply depleted channel (DDC) transistors; block 30 outlines slightly depleted channel (SDC) transistors; block 40 outlines conventional channel doped legacy transistors; and block 50 outlines undoped channel analog transistors. As will be appreciated, these transistor types are representative and not intended to limit the type of transistor device types that can be usefully formed on a die or wafer. The wafer 10 includes a substrate 102 (typically silicon), a lightly p-doped silicon layer 106 that can be secondarily implanted with deep punch through and/or screen layers, and an epitaxial blanket layer 114 grown after implantation of dopants in layer 106, effectively blocking or reducing upward migration of dopants from layer 106 into epitaxial blanket layer 114.

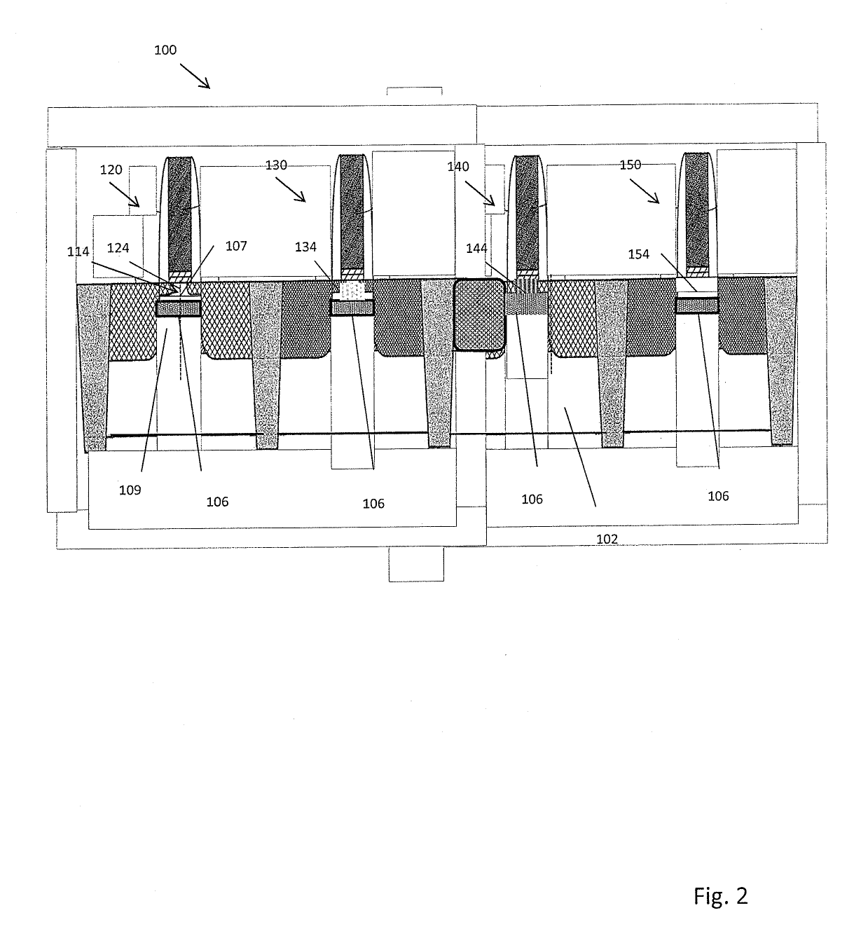

FIG. 2 is a not to scale illustration schematically showing in greater detail the four representative transistor device types constructed on a common substrate 102 to have the commonly doped screen layer 106 and deposited epitaxial blanket layer 114 on which a channel for a field effect or other transistor is defined.

In FIG. 2, the DDC transistor 120 includes a gate, source, and drain that together define a channel 124. In operation, the channel 124 is deeply depleted, forming what can be described as a deeply depleted channel with depletion depth under the gate set by a highly doped screen layer 106. While the channel 124 is substantially undoped, the epitaxial blanket layer 114 may include simple or complex layering with different dopant concentrations. This doped layering can optionally include a threshold voltage set region 107, with a dopant concentration less than screen layer 106, positioned between the gate and the screen layer 106. A threshold voltage set region 107 permits small adjustments in operational threshold voltage of the DDC transistor 120 and can be formed by out diffusion from the screen layer, in-situ or delta doping during epitaxial growth, or with tightly controlled implants. In particular, that portion of the channel adjacent to the gate should remain undoped. Embodiments of various DDC transistor structures and manufacturing processes are more completely described in U.S. application Ser. No. 12/708,497 titled “Electronic Devices and Systems, and Methods for Making and Using the Same”, in U.S. application Ser. No. 12/971,884 titled “Low Power Semiconductor Transistor Structure and Method of Fabrication Thereof”, in U.S. application Ser. No. 12/971,955 titled “Transistor with Threshold Voltage Set Notch and Method of Fabrication Thereof”, and in U.S. application Ser. No. 12/895,785 titled “Advanced Transistors With Threshold Voltage Set Dopant Structures”, the disclosures of which are hereby incorporated by reference herein in their entirety.

In certain embodiments, the screen layer 106 is doped to have a concentration between about 5×10¹⁸ dopant atoms per cm³ and about 1×10²⁰ dopant atoms per cm³, significantly more than the dopant concentration of the undoped channel 124 and at least slightly greater than the dopant concentration of the optional threshold voltage set region 107. Screen layer 106 and threshold voltage set region 107 are both comprised of dopants of opposite type from the doped source and drains. For instance, if the source and drains are doped with P-type material, then screen layer 106 and threshold voltage set region 107 use N-type dopants. Exact dopant concentrations and screen layer depths and thicknesses are selected based upon the desired operating threshold voltage and other channel design electrical considerations. Generally, a higher concentration results in a higher threshold voltage. A deeper screen layer 106 (depth measured from gate 120) results in a lower threshold voltage. Typically, the screen layer 106 is formed by way of a selected ion implantation into a lightly doped well (not shown), the process conditions including energy and dose selected to achieve the desired peak concentration, depth, and thickness. To further help control leakage, a punch through suppression region 109 can optionally be formed beneath the screen layer 106. Typically, the punch through suppression region 109 is formed by direct implant into a lightly doped well and can be formed either before or after the screen layer 106 or it can be formed by out diffusion from the screen layer, in-situ growth, or other known process. The punch through suppression region 109 has a dopant concentration less than the screen layer 106, typically set between about 1×10¹⁸ dopant atoms per cm³ and about 1×10¹⁹ dopant atoms per cm³. Typically, the thickness of the punch through suppression region 109 is selected to perform optimal anti junction leakage function. The punch through suppression region 109 dopant concentration is set higher than the overall dopant concentration of the well substrate.

In the embodiment at FIG. 2, the threshold voltage set region 107 is positioned above screen layer 106 and is typically formed as a thin doped layer, preferably by ion implantation into screen layer 106 using a lesser energy and dose than used for screen layer 106. Providing threshold voltage set region 107 affords another knob by which threshold voltage can be set for a device. Suitably varying dopant concentration, thickness, and separation from the gate dielectric and the screen layer 106 allows for controlled slight adjustments of threshold voltage in the operating transistor. In certain embodiments, the threshold voltage set region 107 is doped to have a concentration between about 1×10¹⁸ dopant atoms per cm³ and about 1×10¹⁹ dopant atoms per cm³. The threshold voltage set region 107 can be formed by several different processes, including 1) in-situ epitaxial doping, 2) epitaxial growth of a thin layer of silicon followed by a tightly controlled dopant implant (e.g delta doping), 3) epitaxial growth of a thin layer of silicon followed by dopant diffusion of atoms from the screen layer 106, or 4) by any combination of these processes (e.g. epitaxial growth of silicon followed by both dopant implant and diffusion from the screen layer 106). The channel 124 contacts and extends between the source and the drain, and supports movement of mobile charge carriers between the source and the drain. Channel thickness can typically range from 5 to 50 nanometers, with exact thickness being dependent on desired transistor operating characteristics and transistor design node (i.e. a 20 nm gate length transistor will typically have a thinner channel thickness than a 45 nm gate length transistor). In certain embodiments, dopant migration resistant layers of carbon, germanium, or the like can be applied along with or above screen layer 106 to further limit dopant migration.

The SDC transistor 130 can have a screen layer doped to have the same or similar dopant concentration as DDC transistor 120. However, it is distinct from the DDC transistor 120 in that implants, in-situ epitaxial growth, controlled screen layer out-diffusion, or other dopant positioning methods are used to place a significant amount of dopants in the channel 134. The concentration of dopants can vary, but will be intermediate between DDC transistors 120 that normally are substantially undoped and highly doped conventional or legacy transistors 140 as hereafter described. Typically, whereas a DDC transistor 120 may keep the epitaxial layer substantially undoped (intrinsically, this amounts to approximately 1×10¹⁷ atoms/cm³), a typical legacy transistor 140 uses dopants in the channel at approximately 4 to 5×10¹⁸ atoms/cm³. In contrast, the SDC transistor 130 limits the concentration of dopants in the channel 134 to approximately half an order of magnitude, or 1×10¹⁸ atoms/cm³. Because of the channel dopants, such SDC transistors 130 can be better matched to legacy transistors 140 than undoped channel DDC transistors 120. Advantageously, such SDC transistors 130 can reduce redesign requirements, can match channel functionality of legacy transistors 140 more closely, and may not need auxiliary bias. In addition, short channel effects are improved, allowing an increase in a lightly doped drain (LDD) dose that provides higher drive current than comparable DDC transistors 120. As will be appreciated, while mobility in the channel 134 is improved relative to a legacy transistor 140 and Vt variations are reduced, an SDC transistor 130 will not generally have the mobility and low Vt variations of a comparable DDC transistor 120. This is seen in the following Table 1 that compares a DDC transistor 120 to an SDC transistor 130 for a 65 nm fabrication process.

TABLE 1

| | Ion | Ioff | | | DIBL | | AVT |
|---|---|---|---|---|---|---|---|
| | (uA/um) | (nA/um) | Vthsat (V) | Vthlin (V) | (mV/V) | RDF | (mV · um) |
| DDC | 958 | 0.9 | 0.327 | 0.42 | 97.89474 | 0.169741 | 0.636066 |
| SDC | 988 | 0.9 | 0.351 | 0.478 | 133.6842 | 0.952628 | 1.132814 |

As can be seen from consideration of Table 1, an SDC transistor 130 gives better drive but higher RDF and AVT as compared to a DDC transistor 20.

A legacy transistor 140 is a conventional transistor that includes a doped channel 144 for setting threshold voltage. Threshold voltage may be set by way of either channel dopant implants and/or halo (alternatively known as “pocket”) implants. Typically, doping concentration within channel 144 is approximately 4 to 5×10¹⁸ atoms/cm³, in contrast to the case of a DDC transistor 120 where the epitaxial layer portion of the channel 124 remains undoped which amounts to approximately 1×10¹⁷ atoms/cm³ intrinsic. For certain embodiments, to achieve a legacy transistor 140, screen layer implants 106 can be omitted, or extended subjected to counterdoping, or otherwise altered to allow closer matching of legacy characteristics with those of DDC transistors 120. While such legacy transistors 140 have poor performance for many applications as compared to DDC transistors 120 or SDC transistors 130, they can be useful for minimizing redesign of specialty circuit blocks. Performance of a legacy transistor 140 versus a SDC transistor 130 is indicated in the following Table 2.:

TABLE 2

| | Ion | Ioff | | | DIBL | | AVT |
|---|---|---|---|---|---|---|---|
| | (uA/um) | (nA/um) | Vthsat (V) | Vthlin (V) | (mV/V) | RDF | (mV · um) |
| Legacy | 881 | 0.9 | 0.32 | 0.46 | 147.3684 | 1.316359 | 1.452091 |
| SDC | 988 | 0.9 | 0.351 | 0.478 | 133.6842 | 0.952628 | 1.132814 |

As seen in Table 2, an SDC transistor 130 provides better drive and better RDF and AVT as compared to legacy transistors 140 formed via halo implant process.

An analog undoped transistor 150 is also illustrated in FIG. 2. In contrast to the other illustrated transistor types, channel 154 is substantially undoped and there are no provided threshold voltage, channel, or halo implants. Such analog transistors 150 can have extremely low noise operation and may not even require lightly doped drains (LDDs) or other structures for operation.

All transistors of FIG. 2 are substantially planar and preferably formed in bulk silicon. They are preferably fabricated starting with the same base channel layer but the relative undoped channel portions differ from transistor to transistor depending on the threshold voltage and other characteristics of the transistors that are desired.

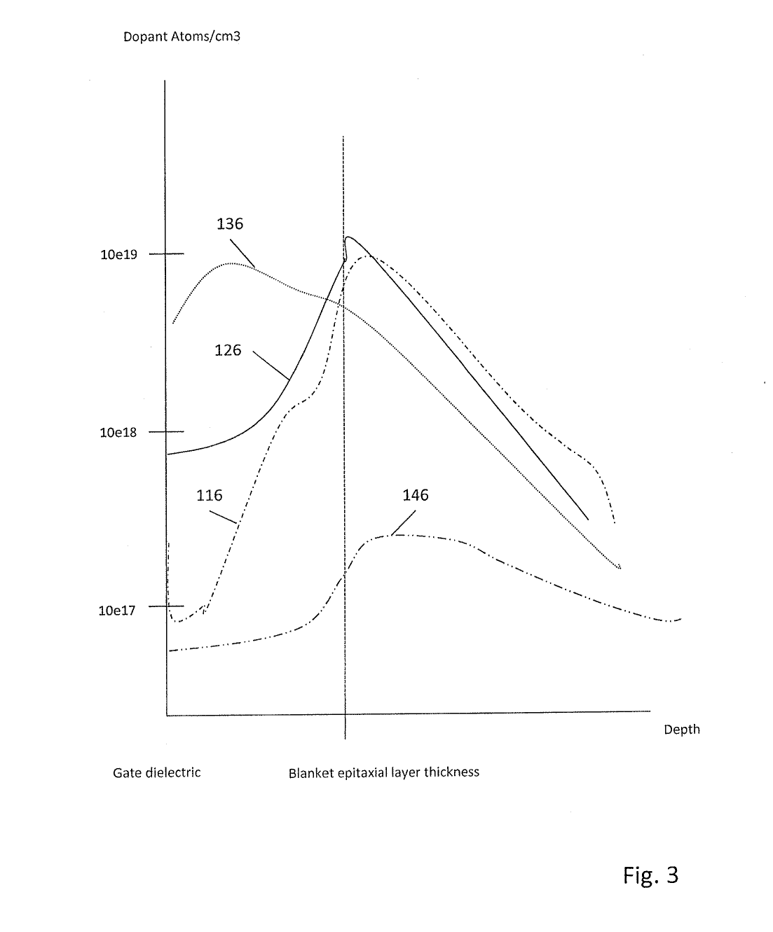

FIG. 3 illustrates representative dopant concentration as a function of depth beneath a gate. Curves are defined with respect to thickness of an epitaxial channel layer below a gate dielectric as indicated. Typical values of blanket epitaxial layer thickness are between 5 and 50 nanometers, with ranges of 10 to 30 nanometers being broadly useful for a wide range of transistor device types. Channels 124, 134, 144, and 154 may be formed from a common epitaxial blanket layer 114 or separately formed as desired. Curve 116 illustrates a DDC type transistor 120 with extremely low dopant concentrations near the gate dielectric, and a threshold voltage set region 107 formed in this embodiment by out-diffusion and thereby forming a notch in the profile adjacent to a screen layer 106 peak below the channel 124. Similarly, curve 126 illustrates an SDC type transistor 120, with significant channel 134 doping, and curve 136 illustrates a conventional legacy transistor 140 with a highly doped channel 144. Curve 146 illustrates an analog transistor 150 with an undoped channel 154 and lower concentration screen layer 106 to reduce noise. As previously noted, the legacy transistor 140 has a dopant defined depletion region under the gate that terminates near the peak dopant concentration in the channel 144, rather than terminating at a screen layer 106 peak as for DDC transistors 120, SDC transistors 130, and analog transistors 150.

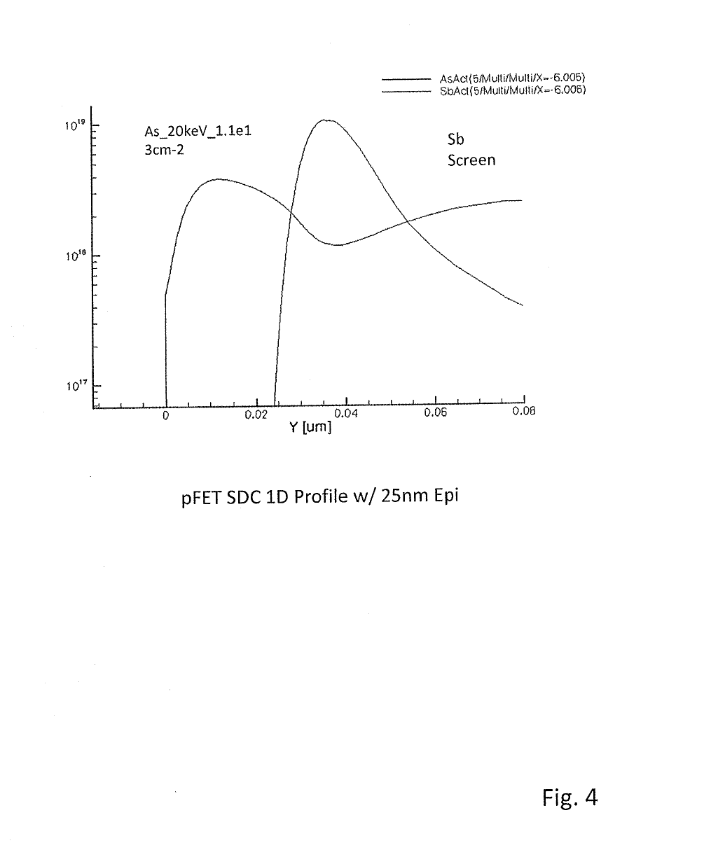

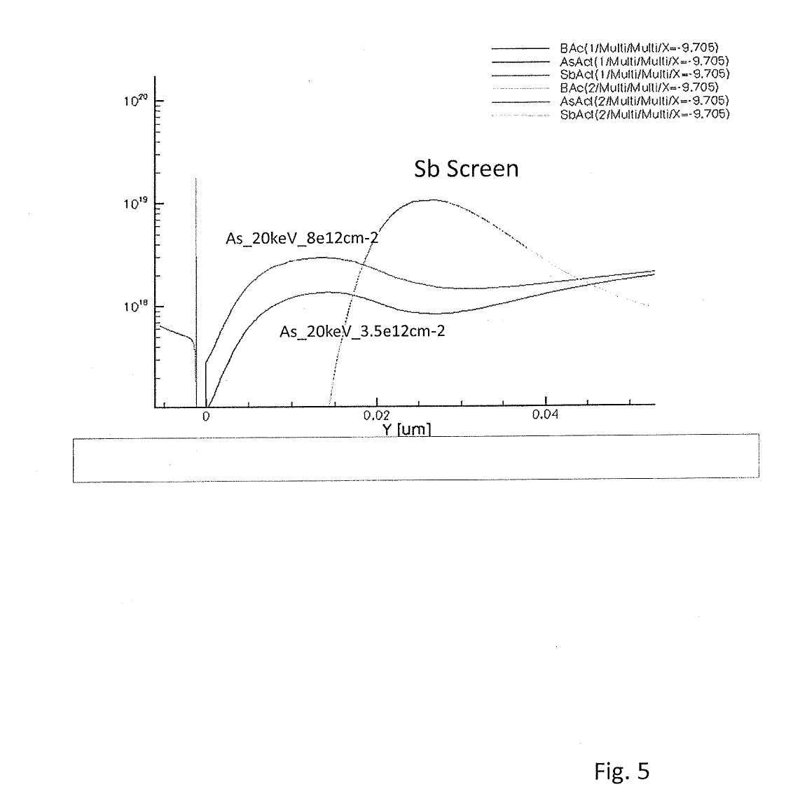

Other variations in dopant profiles, including use of multiple dopant type implants with differing diffusion characteristics (e.g. a slow diffusing, small diffusion constant antimony (Sb) screen, and a faster diffusing, higher diffusion constant arsenic (As) epitaxial channel dopant), are illustrated with respect to FIGS. 4 and 5. FIG. 4 illustrates a potential dopant profile for an SDC type P-FET transistor with an epitaxial layer 25 nanometers thick. FIG. 5 illustrates another antimony screen/arsenic SDC transistor with implant energy conditions indicated. As indicated in both FIG. 4 and FIG. 5, the contemplated channel profile provides a curve representing an Sb screen layer embedded down a depth of the epitaxial layer. Typically, the Sb is formed by ion implantation on or into the underlying well (or anti-punch through region, if any) using an energy of approximately 25 to 30 keV for a dose of about 1 to 1.5×10¹³/cm². Doses and energy levels for the Sb may vary depending on the targeted screen layer peak concentration and depth relative to the gate. The subsequent As layer can be formed a number of ways, including by ion implantation into the epitaxial layer at an energy of about 20 keV to achieve the depth desired for the peak concentration. Or, the As region can be formed by ion implantation on or into the screen layer at a reduced energy, about 3 to 6 keV, and, subsequent to the As ion implantation, the epitaxial layer may be formed. Still another alternative is to implant the As first on or into the well (or anti-punch through region) and subsequently implant the Sb, the energies for each ion implantation selected to result in the Sb screen layer being embedded to a desired depth below the gate and the As being targeted for a location above the Sb screen. Dose for the As is selected to achieve the peak concentration in the desired location, where the dose may generally be about 5×10¹² to 2×10¹³/cm². Subsequent to the As ion implantation, a thermal cycling may be applied using rapid thermal anneal or other preferred methods to achieve a final profile for the As with a degree of controlled upward diffusion. Once the temperature is selected to achieve the desired profile, which temperature may be in a range of approximately 600 to 900 degrees C. or may be higher if a spike anneal method is used, subsequent steps which include anneal should be implemented within a selected thermal budget based upon the diffusion characteristics of the dopants so as to avoid unwanted profile changes. As a general matter, the final location of the As is selected based upon the desired Vt for a desired Vt variation for the SDC transistor while controlling short-channel effects. To avoid excessive Vt variation, the concentration of the As in the channel is limited to be approximately ½ an order of magnitude lower than typical channel dopant concentration levels for a legacy transistor. In some instances, the extent of migration upward from the origin of the dopant placement by the ion implantation step is limited to ensure a defined intrinsic epitaxial layer portion. In other scenarios, a moderate concentration of As, for instance approximately 1×10¹⁸/cm³, may be allowed to migrate up to touching or nearly touching the gate oxide for other electrical benefits within the channel including control of effective gate length.

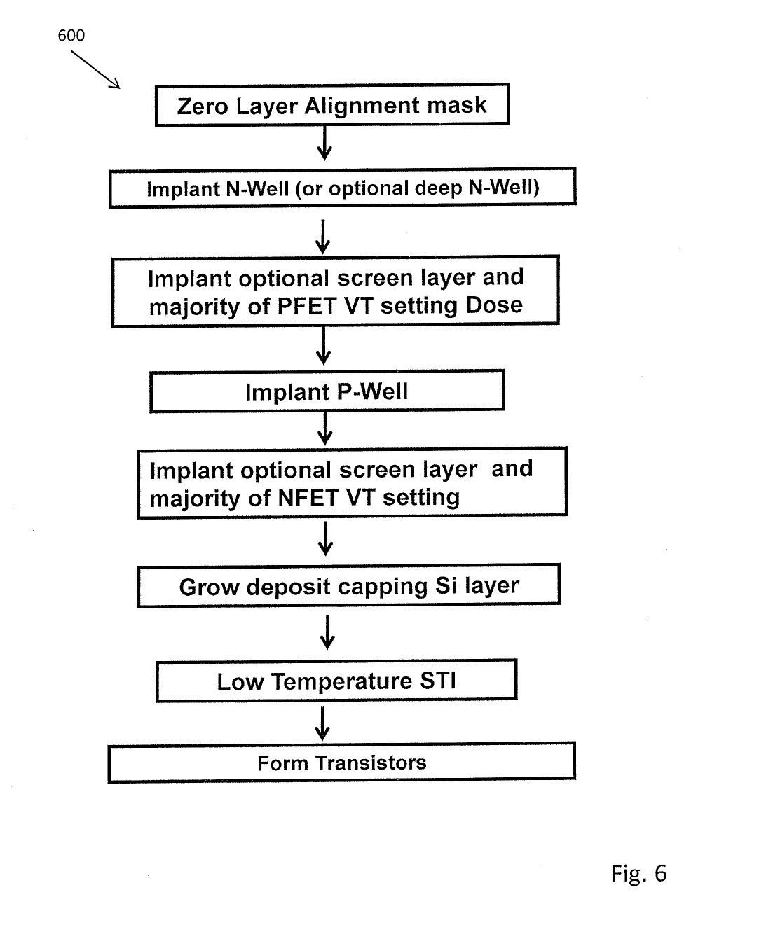

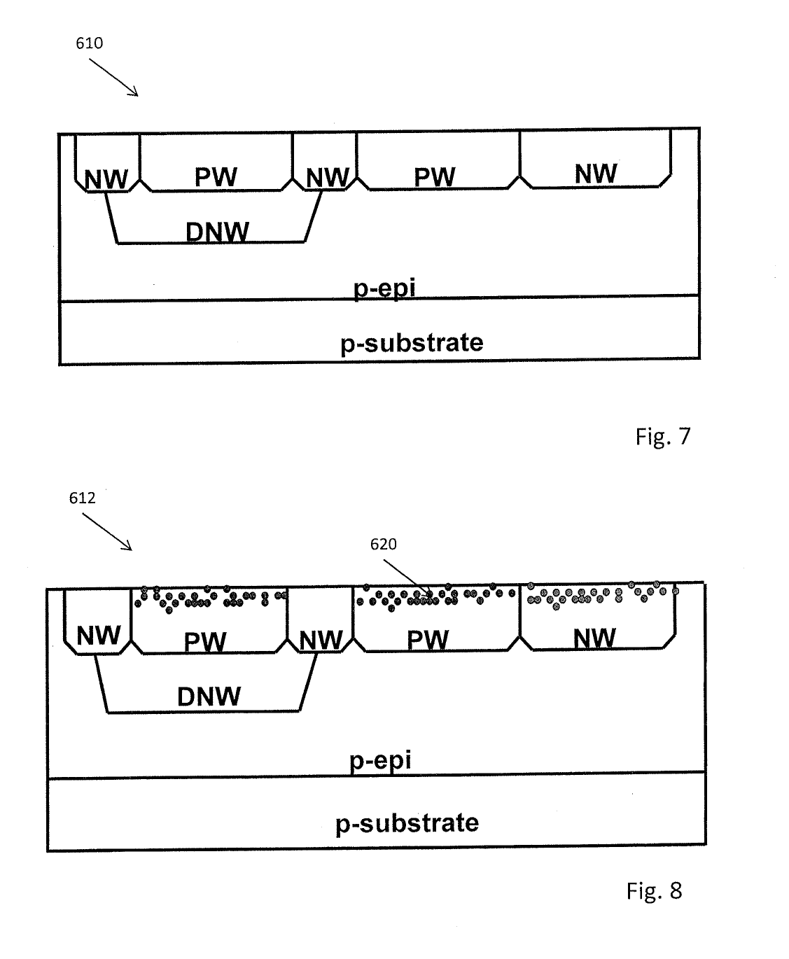

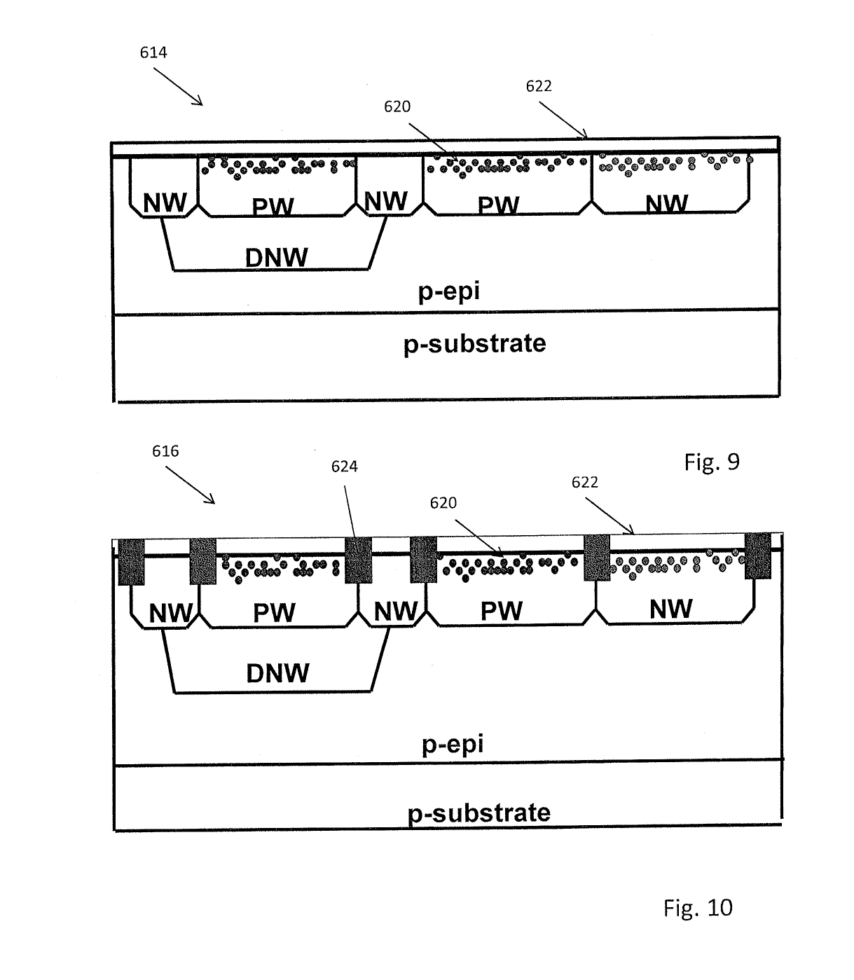

One embodiment 600 of a portion of a transistor manufacturing process is illustrated by FIG. 6 and related FIGS. 7-10. A wafer is masked with a “zero layer” alignment mask to define dopant implantable well regions. A deep N-well can be optionally formed in combination with a conventional N-well as seen in transistor substrate 610 of FIG. 7. A highly doped screen layer and/or Vt set implant are formed. Preferably, the N-wells, highly doped screen layer, and Vt implant are all formed by way of ion implantation using selected energies and doses to result in a desired depth, dopant concentration, and thickness tailored for the desired device electrical characteristics. For a DDC transistor, typically the screen layer is concentrated on the order of 5×10¹⁸ to 1×10²⁰ atoms/cm³. The depth and concentration of the screen layer itself can also serve to adjust threshold voltage. In certain embodiments, a separate threshold voltage set region can be implanted such that the threshold voltage set region is of a peak concentration on the order of 1×10¹⁸ to 1×10¹⁹ atoms/cm³. Typically, for a P-FET, N-type dopant species such as Sb, P, As, or combinations thereof are used for the wells, screen, and Vt implants. After masking the N-well, the P-well is implanted. Note that the order of forming the N-well and P-well masking steps can be reversed. Again, a screen layer and/or Vt set implant can also optionally be formed, as indicated by dopants 620 in transistor substrate 612 of FIG. 8. Preferably, the P-wells, highly doped screen layer, and Vt implants are all formed by way of ion implantation using selected energies and doses to result in a desired depth, dopant concentration, and thickness tailored for the desired device electrical characteristics. For a DDC transistor, typically the screen layer is concentrated on the order of 5×10¹⁸ to 1×10²⁰ atoms/cm³. The screen layer itself can also serve as the threshold voltage set region. Or, a separate threshold voltage set region can be implanted such that the threshold voltage set region is of a peak concentration on the order of 1×10¹⁸ to 1×10¹⁹ atoms/cm³. Typically, for a N-FET, P-type dopant species such as B are used for the wells, screen, and Vt implants. Though not shown, additional steps including pre-amorphization using Ge implant and doping the amorphized region with C may be included to inhibit migration of B. Additionally, other well implants such as punch through implants can also be formed in each of the respective P and N-wells, before or after screen layer implantation. When the dopants have been placed, a capping epitaxial layer 622 is deposited/grown as seen in transistor substrate 614 of FIG. 9. Typically the layer is silicon, but silicon germanium or other non-silicon in-situ deposited atoms can also be added to the epitaxial layer. Any doping material may be selected so as to minimize electrical conductivity effects and allow the epitaxial layer to behave as closely as possible to intrinsic silicon. For purposes of this description, we shall refer to the epitaxial layer as intrinsic. In certain embodiments, portions of the intrinsic epitaxial layer can be thinned, allowing, for example, for a thinner SDC or to form a legacy transistor layer while retaining a relatively thicker DDC epitaxial layer. To thin portions of the epitaxial layer, typically either a thermal cycling is performed to allow differential out-diffusion to occur from the previously doped areas. Degrees of out-diffusion are preferably controlled by a controlled thermal cycling and then maintaining the remainder of the fabrication within a pre-set thermal budget. Additionally, if desired, there may also be a selective inclusion of anti-migration material in the areas that are not to be diffused, such as carbon, wherein such anti-migration material is preferably implanted prior to the formation of the intrinsic epitaxial layer. A further or alternative way to thin portions of the intrinsic epitaxial layer is to perform a channel implant directly into the intrinsic epitaxial layer so that, effectively, there results in a thinner undoped region. To complete a legacy transistor, typically a halo structure is formed after the source/drain structures are created. For the SDC and DDC transistors, a halo structure is not used.

Following epitaxial growth, shallow trench isolation (STI) structures 624 are formed using a combination of patterning, etch, and fill steps using electrically insulative material in the trenches so as to electrically separate the wells, as seen in transistor substrate 616 of FIG. 10. Gate structures, spacers, contacts, stress implants, tensile films, dielectric coatings, and the like are then completed to form operable transistors. Other advantages and possible process variations are discussed in particular in U.S. application Ser. No. 12/708,497, U.S. application Ser. No. 12/971,884, and U.S. application Ser. No. 12/971,955, all of which were previously incorporated by reference herein.

Transistors created according to the foregoing embodiments, structures, and processes can include PMOS or NMOS transistors, digital logic or analog transistors, legacy (highly doped channel transistors), or improved slightly doped channel (SDC) transistors, and can be formed on the die alone or in combination with other transistor types. Transistors formed according to the disclosed structures and processes will have a reduced mismatch arising from scattered or random dopant variations as compared to conventional MOS analog or digital transistors. This is particularly important for transistor circuits that rely on closely matched transistors for optimal operation, including differential matching circuits, analog amplifying circuits, and many digital circuits in widespread use such as SRAM cells. Variations can be even further reduced by adoption of structures such as a screen layer, an undoped channel, or a Vt set layer as described herein to further effectively increase headroom which the devices have to operate or to which to design. This allows for improved electronic devices with reduced power, improved sensitivity, and improved performance.

Although the present disclosure has been described in detail with reference to a particular embodiment, it should be understood that various other changes, substitutions, and alterations may be made herein without departing from the spirit and scope of the appended claims. Numerous other changes, substitutions, variations, alterations, and modifications may be ascertained by those skilled in the art and it is intended that the present disclosure encompass all such changes, substitutions, variations, alterations, and modifications as falling within the spirit and scope of the appended claims. Moreover, the present disclosure is not intended to be limited in any way by any statement in the specification.

What is claimed is:

1. A method for fabricating semiconductor structures, comprising:
implanting a screen layer into a substrate, the screen layer formed at least in part from a at least one dopant species,
forming an epitaxial channel layer above the screen layer, and
diffusing one of the dopant species from the screen layer into the epitaxial channel layer to form a slightly depleted channel (SDC) transistor.

2. The method of claim 1, wherein the epitaxial channel layer is formed as a blanket epitaxial layer that extends across multiple transistor device types, with at least one of the transistor device types being processed so that at least a portion of the epitaxial channel layer remain substantially undoped.

3. The method of claim 1, further comprising implanting a first and a second dopant species having different diffusion characteristics into the screen layer.

4. The method of claim 3, wherein the first dopant species comprises antimony and the second dopant species comprises arsenic, and further including the step of diffusing the arsenic into the epitaxial channel layer to form an SDC device.

5. The method of claim 1, wherein the epitaxial channel layer is between 5 and 50 nanometers in thickness.

6. The method of claim 1, further comprising:
forming the epitaxial channel layer as a blanket epitaxial layer that extends across multiple transistor device types, and
forming shallow trench isolation structures between at least some of the multiple transistor device types after the formation of the epitaxial layer.

7. The method of claim 1, wherein the epitaxial channel layer includes a dopant concentration less than the screen layer dopant concentration, with doping of the epitaxial channel layer occurring without direct ion implantation into the grown epitaxial channel layer.

8. The method of claim 1, further comprising forming a dopant migration resistant layer formed along with or above the screen layer, the dopant migration resistant layer reduces upward migration of dopants from the screen layer into the epitaxial channel layer.

9. The method of claim 8, wherein the dopant migration resistant layer includes carbon or germanium.
